(19) United States
(12) Patent Application Publication
(10) Pub. No.: US 2005/0274007 A1
(43) Pub. Date: Dec. 15, 2005

(54) Method for increasing a production rate of printed wiring boards

(75) Inventors: Wen-Ren Tsai, Taoyuan Hsien (TW); Shung-Chin Chen, Taoyuan Hsien (TW)

Correspondence Address: BACON & THOMAS, PLLC, 625 SLATERS LANE, FOURTH FLOOR, ALEXANDRIA, VA, 22314, US

(73) Assignee: Geetmann Taiwan Ltd., Taoyuan Hsien (TW)

(21) Appl. No.: 10/994,553

(22) Filed: Nov. 23, 2004

(30) Foreign Application Priority Data
Jun. 10, 2004 (TW) 093116648

(51) Int. Cl. H01L 23/495

(52) U.S. Cl. 29/830; 29/829; 29/846; 29/847

(57) ABSTRACT

A method for increasing a production rate of printed wiring boards has the following steps: applying a conductive layer to an isolating base board; drilling at least one first conductive layer and the isolating base board to form multiple through holes; plating the through holes with a conductive material to form an inner conductive layer; implementing a plating process; plating the set of wires with a conductive material such as copper to form a third conductive layer and thereby increasing a width of each wiring and shorten a distance between adjacent wires; and applying a solder resist on portions of the wires. The method of the invention maintains the width of the wiring in an appropriate value by plating the wiring. Therefore, the quality and the production rate of printed wiring boards are improved.

### BACKGROUND OF THE INVENTION

1. Field of the Invention

The present invention relates to a method for manufacturing a wiring board, and more particularly to a method for increasing a production rate of printed wiring boards.

2. Description of Related Art

A printed wiring board is a transit product further processed such as by having electrical capacitors or mounted on it to finally become a printed circuit board (PCB). The quality and production rate of the printed wiring board directly effect the output of the PCBs.

A conventional method for manufacturing a printed wiring board in accordance with the prior art comprises the steps as follows:

(1) applying a conductive layer such as a copper foil to an isolating base board.

(2) drilling the conductive layer and the isolating base to form multiple through holes;

(3) plating the through holes (PTH);

(4) applying a photo resist on portions of a top surface of the conductive layer and transferring images onto the portions of the photo resist by using ultraviolet (UV) to harden portions of the photo resist;

(5) removing the portions of the photo resist not hardened and etching the uncovered portions of the conductive layer with an etchant to make the covered portions of the conductive layer become a set of wires;

(6) implementing automated optical inspection (AOI) to the set of the wires;

(7) applying a solder resist on portions of the wires;

(8) plating certain uncovered portions of the wires with nickel (Ni) or Aurum (Au) to form a printed wiring board; and

(9) follow-up processes such as washing the printed wiring board.

To maintain an effective production rate of the printed wiring boards, a width of the wires and a distance of adjacent wires must be sized precisely. The value of the width of the wire lower or higher than a standard value will cause a broken circuit or shorten the distance between adjacent wires and increase the risk of having electromagnetic interference (EMI) among wires and possibly cause a short circuit. However, etching the conductive layer causes the wire to have an unstable width that is frequently lower than the standard value. Therefore, the production rate of the printed wiring board is low. In addition, a chip or electrical capacitor is connected to multiple bonding fingers formed respectively on distal ends of the corresponding wires of the printed wiring board by bonding multiple metal wires between the chip and the bonding fingers after completion of the printed wiring board. A width of the bonding finger effects the bonding rate of the feet. However, etching the conductive layer also makes the width of the bonding finger unstable and impairs the rate of bonding the metal wires. Therefore, the production rate of the printed wiring board is low.

To overcome the shortcomings, the present invention provides a method for increasing a production rate of printed wiring boards to mitigate or obviate the aforementioned problems.

### SUMMARY OF THE INVENTION

The main objective of the invention is to provide a method for increasing a production rate of printed wiring boards.

The method for increasing a production rate of printed wiring boards comprises following steps:

applying at least one first conductive layer to an isolating base board;

drilling the at least one first conductive layer and the isolating base board to form multiple through holes;

plating peripheries defining the through holes with a conductive material to form a inner conductive layer; implementing a plating process; plating the set of wires with a conductive material such as copper to form a third conductive layer and thereby increasing a width of each wire and shortening a distance between adjacent wires;

implementing automated optical inspection to the set of wires;

applying a solder resist on portions of the wires; and

plating uncovered portions of the wires with nickel or Aurum to form an enhanced conductive layer.

Other objectives, advantages and novel features of the invention will become more apparent from the following detailed description when taken in conjunction with the accompanying drawings.

### BRIEF DESCRIPTION OF THE DRAWINGS

FIGS. 1A to 1K are flow diagrams of a first embodiment of a method for increasing a production rate of printed wiring boards in accordance with the present invention;

FIGS. 2A to 2K are flow diagrams of a second embodiment of a method for increasing a production rate of printed wiring boards in accordance with the present invention;

FIGS. 3A1 and 3A2 are flow diagrams of a method for increasing a production rate of printed wiring boards in accordance with the present invention, wherein FIG. 3A2 is a sectional view along line 3A2-3A2 in FIG. 3A1;

FIG. 3B1 and 3B2 are flow diagrams of the method for increasing a production rate of printed wiring boards in FIGS. 3A1 and 3A2 showing that the wires are plated, wherein FIG. 3B2 is a sectional view along line 3B2-3B2 in FIG. 3B1;

FIGS. 4A to 4K are flow diagrams of a third embodiment of a method for increasing a production rate of printed wiring boards in accordance with the present invention;

FIGS. 5A to 5K are flow diagrams of a fourth embodiment of a method for increasing a production rate of printed wiring boards in accordance with the present invention;

FIGS. 6A1 and 6A2 are flow diagrams of a method for increasing a production rate of printed wiring boards in accordance with the present invention, wherein FIG. 6A2 is a sectional view along line 6A2-6A2 in FIG. 6A1; and

FIG. 6B13 and 6B2 is are flow diagrams of the method for increasing a production rate of printed wiring boards in FIGS. 6A1 and 6A2 showing that the wires are plated, wherein FIG. 6B2 is a sectional view along line 6B2-6B2 in FIG. 6B11.

### DETAILED DESCRIPTION OF PREFERRED EMBODIMENT

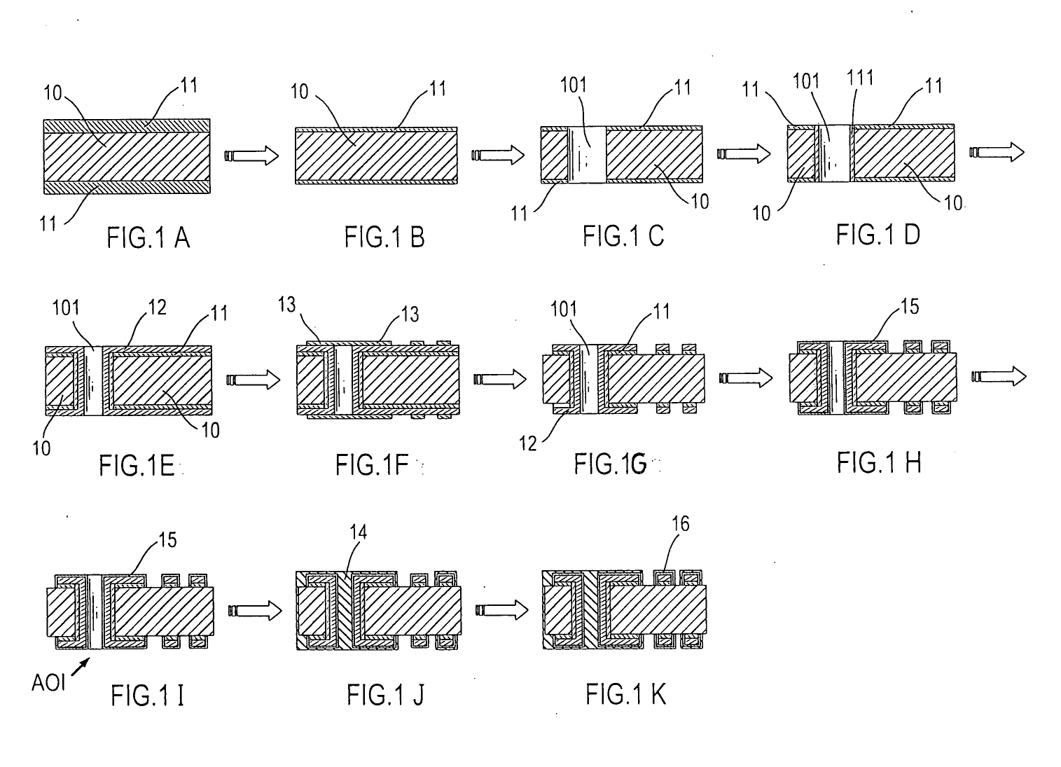

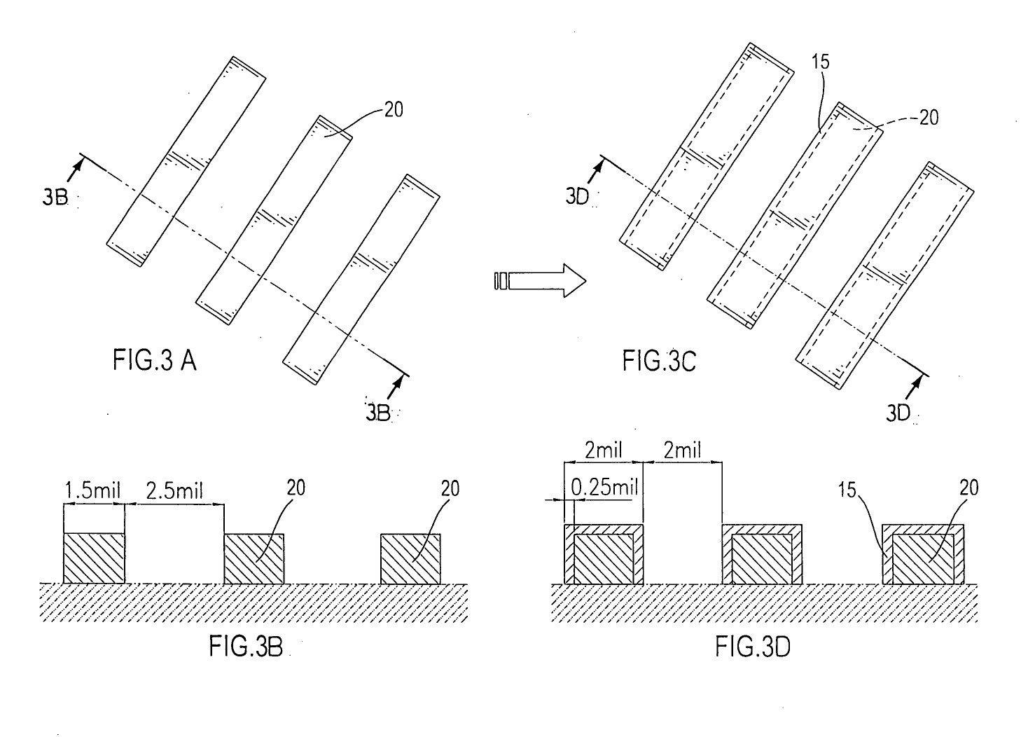

With reference to FIGS. 1A to 1K and FIGS. 3A1, 3A2, 3B1, and 3B2, a method for increasing a production rate of printed wiring boards in accordance with the present invention for improving wiring-forming processes comprises the steps as follow:

(A) applying at least one first conductive layer (11) such as a copper foil to either or both of a top surface and a bottom surface of an isolating base board (10);

(B) thinning the at least one first conductive layer (11) to make a thickness of the at least one first conductive layer (11) as desired;

(C) drilling the at least one first conductive layer (11) and the isolating base board (11) to form multiple through holes (101);

(D) plating peripheries defining the through holes (101) (PTH) with a conductive material such as copper to form an inner conductive layer (111);

(E) implementing a plating process to make a set of wires (20), wherein the plating process can selectively be a panel plating process or a pattern plating process that are described respectively as follows:

With reference FIGS. 1E1 to 1E3, a first embodiment of the method for increasing a production rate of printed wiring boards in accordance with the present invention has the panel plating process having three steps as follow:

(E1) plating the at least one first conductive layer (11) and the inner conductive layer (111) with a conductive material such as copper to form a second conductive layer (12);

(E2) applying a photo resist (13) on portions of an outer surface of the second conductive layer (12) and transferring wiring images onto the portions of the photo resist (13) by using ultraviolet (UV) to harden portions of the photo resist (13);

(E3) removing the portions of the photo resist (13) not hardened and etching the uncovered portions of the at least one first and second conductive layers (11, 12) with an etchant such as copper chloride (CuCl₂) or ferrum chloride (FeCl₃) to make the covered portions of the at least one first and second conductive layers (11, 12) become the set of wires (20);

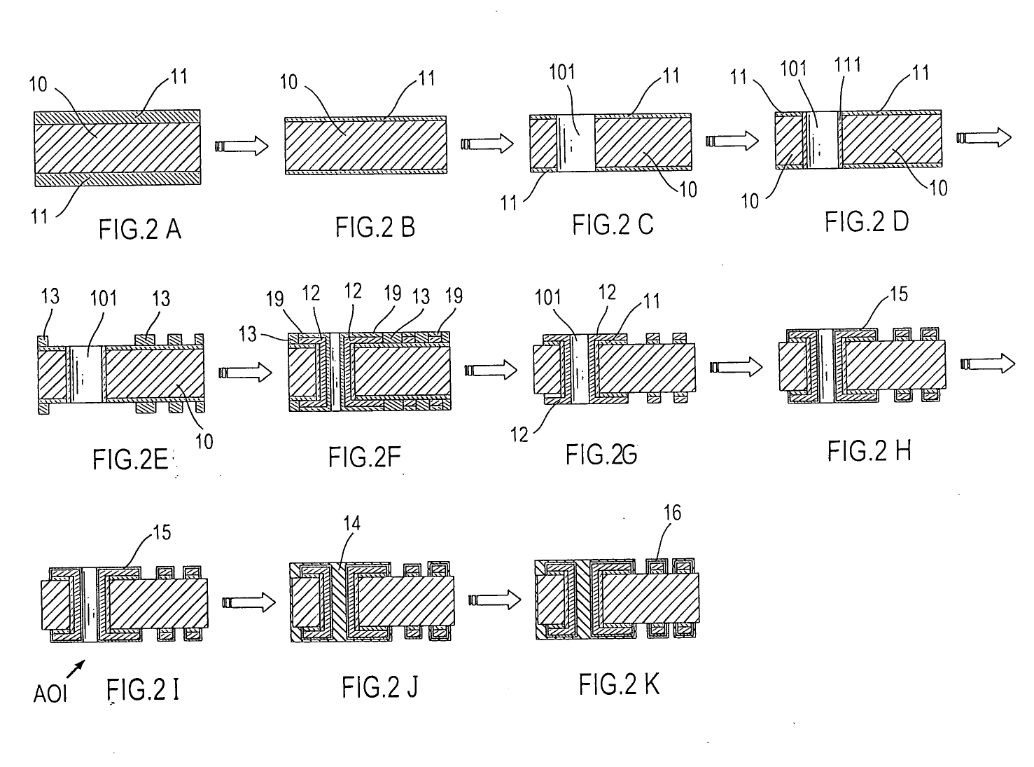

With reference FIGS. 2E1 to 2E3, a second embodiment of the method for increasing a production rate of printed wiring boards in accordance with the present invention has the pattern plating process having three steps as follow:

(E1) applying a photo resist (13) on portions of an outer surface of the at least one conductive layer (11) and transferring wiring images onto the portions of the photo resist (13) by using ultraviolet (UV) to harden portions of the photo resist (13);

(E2) plating uncovered portions of the at least one first conductive layer (11) and the inner conductive layer (111) with a conductive material such as copper to form a second conductive layer (12), then plating the second conductive layer (12) with a metal such as Stannum (Sn) or an alloy of Stannum (Sn) and plumbum (Pb) to form a protective layer (19);

(E3) removing the photo resist (13) and then etching the protective layer (19) and the portions of the at least one first conductive layer (11) covered with the photo resist (13) before and the protective layer (19) to leave the second conductive layer (12) and the portions of the at least one first conductive layer (11), and thereby forming the set of wires (20);

After the step (E), the follow-up steps as described as below are performed:

(H) With reference FIGS. 3A1-A2, 3B1-B2, plating the set of wires (20) with a conductive material such as copper to form a third conductive layer (15) and thereby increasing a width of each wire (20) and shortening a distance between adjacent wires (20); (For example, before plating, the width of each wire (20) and the distance between adjacent wires (20) are respectively 1.5 mil and 2.5 mil and after plating, the width of each wire (20) and the distance between adjacent wires (20) respectively reach standard values 2 mil and 2 mil.)

(I) implementing automated optical inspection (AOI) to the set of the wires (20);

(J) applying a solder resist (14) such as a thermal curable solder resist ink on portions of the wires (20); and

(K) plating uncovered portions of the wires (20) with a fine conductive material such as nickel (Ni) or Aurum (Au) to form an enhanced conductive layer (16).

The above steps are followed-up with processes such as washing the printed wiring board and mounting.

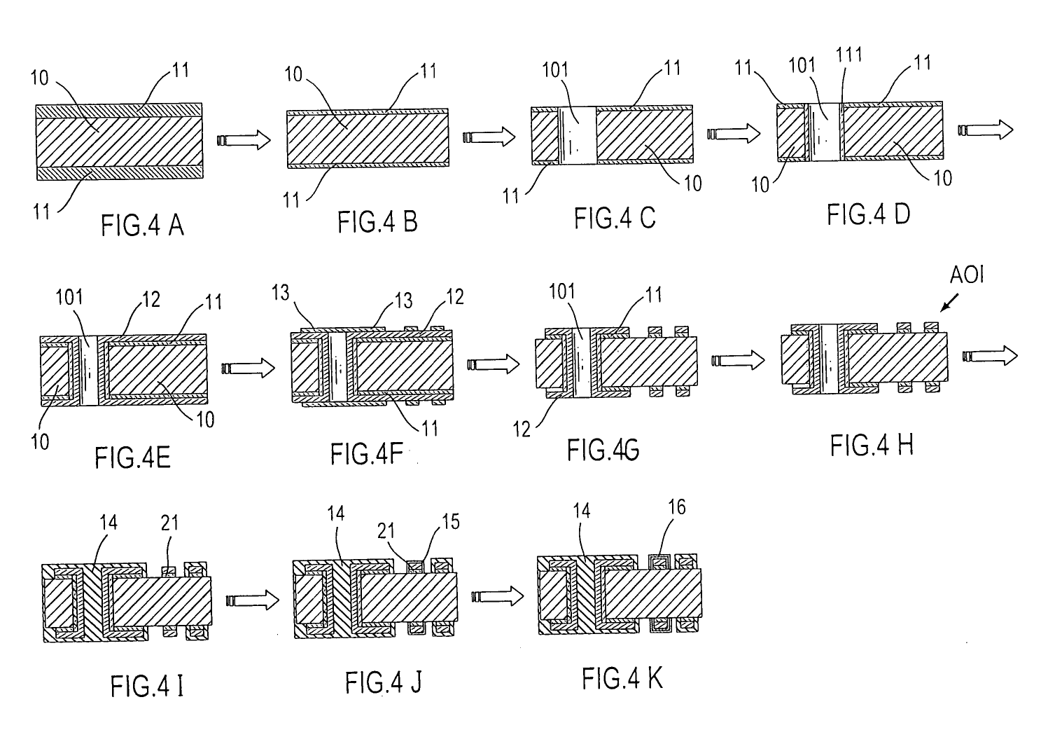

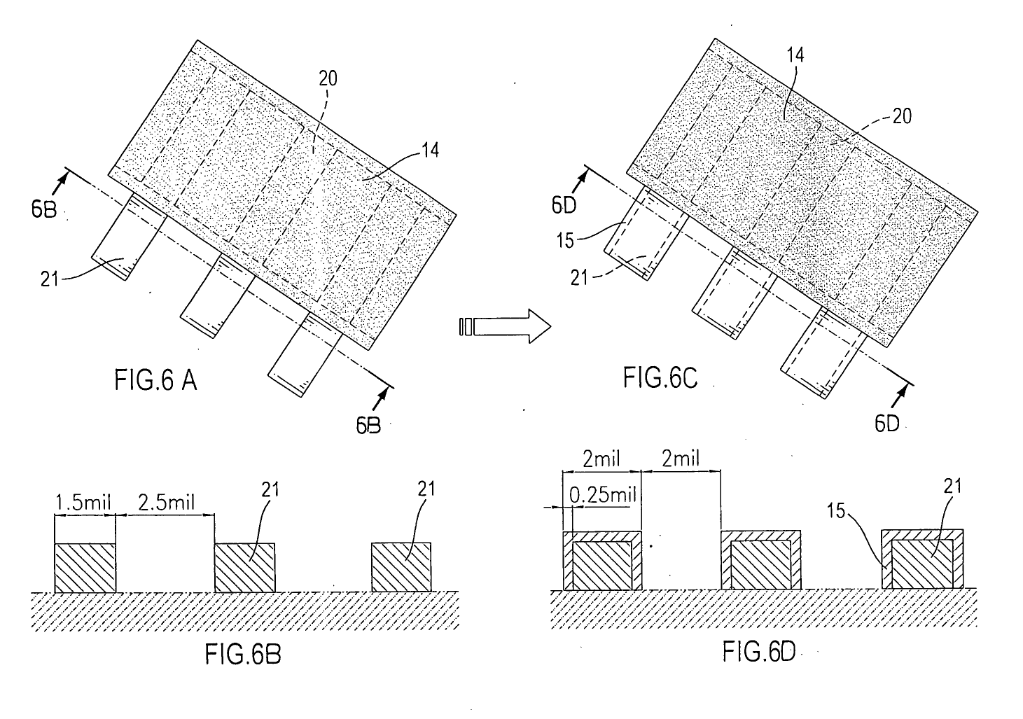

With reference to FIGS. 4A to 4K and FIGS. 6A1, 6A2, 6B1, and 6B2, a method for increasing a production rate of printed wiring boards in accordance with the present invention for improving bonding finger forming processes comprises the steps as follow:

(A) applying at least one first conductive layer (11) such as a copper foil to either or both of a top surface and a bottom surface of an isolating base board (10);

(B) thinning the at least one first conductive layer (11) to make a thickness of the at least one first conductive layer (11) as desired;

(C) drilling the at least one first conductive layer (11) and the isolating base board (11) to form multiple through holes (101);

(D) plating peripheries defining the through holes (101) (PTH) with a conductive material such as copper to form an inner conductive layer (111);

(E) implementing a plating process to make a set of wires (20), wherein the plating process can selectively be a panel plating process or a pattern plating process that are described respectively as follows:

With reference FIGS. 4E1 to 4E3, a third embodiment of the method for increasing a production rate of printed wiring boards in accordance with the present invention has the panel plating process having three steps as follow:

(E1) plating the at least one first conductive layer (11) and the inner conductive layer (111) with a conductive material such as copper to form a second conductive layer (12);

(E2) applying a photo resist (13) on portions of an outer surface of the second conductive layer (12) and transferring wiring images onto the portions of the photo resist (13) by using ultraviolet (UV) to harden portions of the photo resist (13);

(E3) removing the portions of the photo resist (13) not hardened and etching the uncovered portions of the at least one first and second conductive layers (11, 12) with an etchant such as copper chloride (CUCl₂) or ferrum chloride (FeCl₃) to make the covered portions of the at least one first and second conductive layers (11, 12) become the set of wires (20).

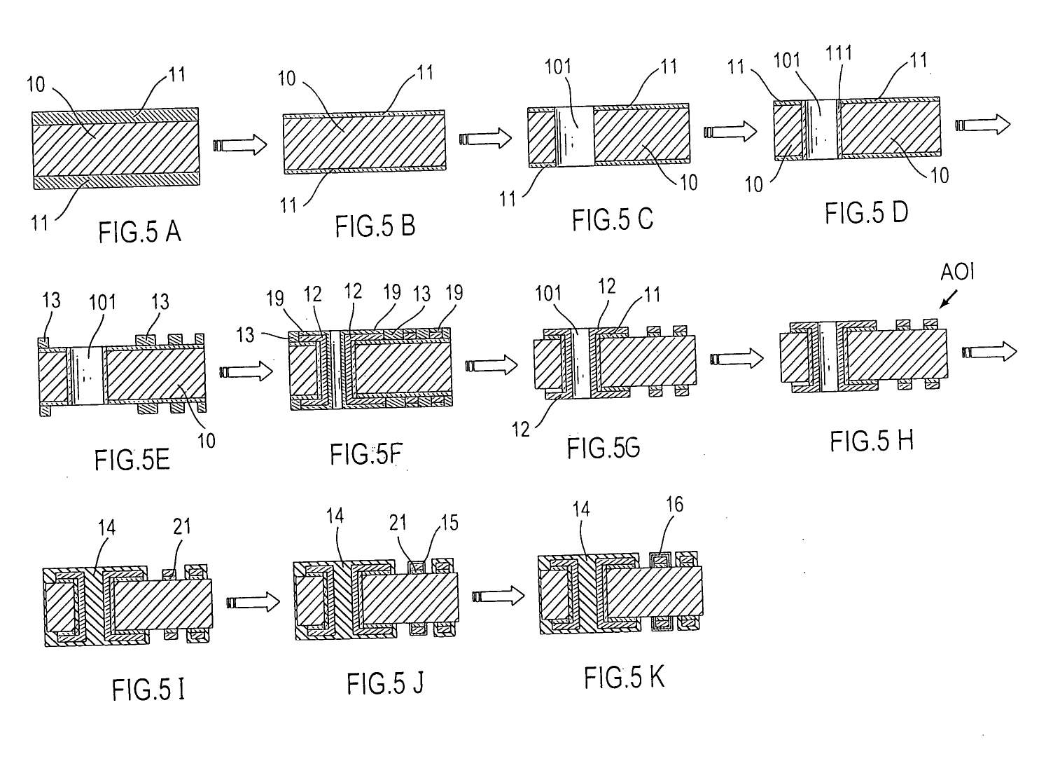

With reference FIGS. 5E1 to 5E3, a fourth embodiment of the method for increasing a production rate of printed wiring boards in accordance with the present invention has a pattern plating process having three steps as follow:

(E1) applying a photo resist (13) on portions of an outer surface of at least one conductive layer (11) and transferring wiring images onto the portions of the photo resist (13) by using ultraviolet (UV) to harden portions of the photo resist (13);

(E2) plating uncovered portions of the at least one first conductive layer (11) and the inner conductive layer (111) with a conductive material such as copper to form a second conductive layer (12), then plating the second conductive layer (12) with a metal such as Stannum (Sn) or an alloy of Stannum (Sn) and plumbum (Pb) to form a protective layer (19);

(E3) removing the photo resist (13) and then etching the protective layer (19) and the portions of the at least one first conductive layer (11) covered with the photo resist (13) before and the protective layer (19) to leave the second conductive layer (12) and the portions of the at least one first conductive layer (11), and thereby forming the set of wires (20).

After the step (E), the follow-up steps as described as below are performed:

(H) implementing automated optical inspection (AOI) to the set of the wires (20);

(I) applying a solder resist (14) such as a thermal curable solder resist ink on portions of the wires (20) to prevent the tin-soldering from forming on any portion other than bonding fingers respectively formed on distal ends of the wires (20); (J) With reference FIGS. 6A1-A2, 6B 1-B2, the bonding fingers of the wires (20) are plated with a conductive material such as copper to form a third conductive layer (15) and thereby a width of each bonding finger is increased and a distance between adjacent bonding fingers is shortened; (For example, before plating, the width of each bonding finger and the distance between adjacent bonding fingers are respectively 1.5 mil and 2.5 mil and after plating, the width of each bonding finger and the distance between adjacent bonding fingers respectively reach standard values 2 mil and 2 mil.) and

(K) plating uncovered portions of the bonding finger with a fine conductive material such as nickel (Ni) or Aurum (Au) to form an enhanced conductive layer (16).

The above steps are followed-up processes with such as washing the printed wiring board.

The method for increasing a production rate of printed wiring boards in accordance with the present invention maintains the width of the wires (20) or bonding finger in an appropriate value by plating the wires (20) or bonding finger. Therefore, the quality and the production rate of printed wiring boards are improved.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

1. A method for increasing a production rate of printed wiring boards comprising following steps:
applying at least one first conductive layer having a thickness and an outer surface to at least one of a top surface and a bottom surface of an isolating base board;
drilling the at least one first conductive layer and the isolating base board to form multiple through holes;
plating the through holes with a conductive material to form an inner conductive layer;
implementing a plating process to make a set of wires;
plating the set of wires with a conductive material to form a third conductive layer and thereby increasing a width of each wire and shortening a distance between adjacent wires;
coducting an automated optical inspection (AOI) of the set of the wires; applying a solder resist to portions of the wires and
plating uncovered portions of the wires with a fine conductive material to form an enhanced conductive layer.

2. The method for increasing a production rate of printed wiring boards as claimed in claim 1, wherein the plating process is a panel plating process having the following steps:
plating the at least one first conductive layer and the inner conductive layer with a conductive material to form a second conductive layer having an outer surface;
applying a photo resist to portions of the outer surface of the second conductive layer and transferring wiring images onto the portions of the photo resist by using ultraviolet radiation to harden portions of the photo resist; and
removing the portions of the photo resist not hardened and etching the uncovered portions of the at least one first and second conductive layers with an etchant to make the covered portions of the at least one first and second conductive form the set of wires.

3. The method for increasing a production rate of printed wiring boards as claimed in claim 1, wherein the plating process is pattern plating process having the following steps:
applying a photo resist to portions of the outer surface of the at least one first conductive layer and transferring wiring images onto the portions of the photo resist by using ultraviolet radiation to harden portions of the photo resist;
plating uncovered portions of the at least one first conductive layer and the inner conductive layer with a conductive material to form a second conductive layer, then plating the second conductive layer with a metal to form a protective layer; and
removing the photo resist and then etching the protective layer and the portions of the at least one first conductive layer covered with the photo resist previously and the protective layer to leave the second conductive layer and the portions of the at least one first conductive layer, and thereby forming the set of wires.

4. The method for increasing a production rate of printed wiring boards as claimed in claim 3, wherein the protective layer is made of tin (Sn).

5. The method for increasing a production rate of printed wiring boards as claimed in claim 3, wherein the protective layer is made of an alloy of tin (Sn) and lead (Pb).

6. A method for increasing a production rate of printed wiring boards comprising the following steps:
applying at least one first conductive layer having a thickness and an outer surface to either or both a top surface and a bottom surface of an isolating base board;
drilling the at least one first conductive layer and the isolating base board to form multiple through holes;
plating the through holes with a conductive material to form an inner conductive layer;
implementing a plating process to make a set of wires;
conducting an automated optical inspection (AOI) of the set of the wires;
applying a solder resists to portions of the wires to prevent the tin-soldering from forming on any portion other than bonding fingers respectively formed on distal ends of the wires;
plating the bonding fingers of the wires with a conductive material to form a third conductive layer and thereby increasing a width of each bonding finger and shortening a distance between adjacent bonding fingers; and
plating uncovered portions of the bonding finger with a fine conductive material to form an enhanced conductive layer.

7. The method for increasing a production rate of printed wiring boards as claimed in claim 6, wherein the plating process is a panel plating process having the following steps:
plating the at least one first conductive layer and the inner conductive layer with a conductive material to form a second conductive layer having an outer surface;
applying a photo resist on portions of the outer surface of the second conductive layer and transferring wiring images onto the portions of the photo resist by using ultraviolet radiation to harden portions of the photo resist; and
removing the portions of the photo resist not hardened and etching the uncovered portions of the at least one first and second conductive layers with an etchant to make the covered portions of the at least one first and second conductive layers become the set of wires.

8. The method for increasing a production rate of printed wiring boards as claimed in claim 6, wherein the plating process is pattern plating process having the following steps:
applying a photo resists to portions of the outer surface of the at least one first conductive layer and transferring wiring images onto the portions of the photo resist by using ultraviolet radiation to harden portions of the photo resist;
plating uncovered portions of the at least one first conductive layer and the inner conductive layer with a conductive material to form a second conductive layer, then plating the second conductive layer with a metal to form a protective layer; and
removing the photo resist and then etching the protective layer and the portions of the at least one first conductive layer covered with the photo resist before and the protective layer to achieve the second conductive layer and the portions of the at least one first conductive layer, and thereby form the set of wires.

9. The method for increasing a production rate of printed wiring boards as claimed in claim 8, wherein the protective layer is made of an tin (Sn).

10. The method for increasing a production rate of printed wiring boards as claimed in claim 8, wherein the protection layer is made of an alloy of tin (Sn) and lead (Pb).

11. The method for increasing a production rate of printed wiring boards as claimed in claim 2 further comprising a step after applying the at least one first conductive layer to the isolating base board:
thinning the at least one first conductive layer to reduce the thickness of the at least one first conductive layer.

12. The method for increasing a production rate of printed wiring boards as claimed in claim 3 further comprising a step after applying the at least one first conductive layer to the isolating base board:
thinning the at least one first conductive layer to reduce the thickness of the at least one first conductive layer.

13. The method for increasing a production rate of printed wiring boards as claimed in claim 6 further comprising a step after applying the at least one first conductive layer to the isolating base board:
thinning the at least one first conductive layer to reduce the thickness of the at least one first conductive layer.

14. The method for increasing a production rate of printed wiring boards as claimed in claim 7 further comprising a step after applying the at least one first conductive layer to the isolating base board:
thinning the at least one first conductive layer to reduce the thickness of the at least one first conductive layer.
